(19) United States
(12) Patent Application Publication
(10) Pub. No.: US 2023/0068261 A1
(43) Pub. Date: Mar. 2, 2023

(54) DISPLAY DEVICE

(71) Applicant: Innolux Corporation, Miao-Li County (TW)

(72) Inventors: Yu-Chia Huang, Miao-Li County (TW); Jia-Yuan Chen, Miao-Li County (TW); Tsung-Han Tsai, Miao-Li County (TW); Kuan-Feng Lee, Miao-Li County (TW)

(73) Assignee: Innolux Corporation, Miao-Li County (TW)

(21) Appl. No.: 17/862,412

(22) Filed: Jul. 12, 2022

(30) Foreign Application Priority Data
Aug. 25, 2021 (CN) 202110980907.9

(51) Int. Cl. H01L 33/64; H01L 27/15

(52) U.S. Cl. CPC H01L 33/642; H01L 27/156

(57) ABSTRACT

A display device and another display device are provided. The display device includes a substrate, multiple light emitting units, a first and a second structures. The light emitting units are disposed on the substrate and generate heat. The first structure is disposed on the substrate. The second structure is disposed outside of the substrate. The heat is transferred from the light emitting units to the second structure through the first structure. Another display device includes a substrate, multiple light emitting units, a first and a second structures. The light emitting units are disposed on the substrate and generate heat. The first structure is disposed on the substrate and transfers the heat. In a top view of another display device, an area of a portion of the first structure is greater than an area of a portion of the light emitting units in a predetermined square region of the substrate.

### CROSS-REFERENCE TO RELATED APPLICATION

This application claims the priority benefit of Chinese application serial no. 202110980907.9, filed on Aug. 25, 2021. The entirety of the above-mentioned patent application is hereby incorporated by reference herein and made a part of this specification.

### BACKGROUND

### Technical Field

The disclosure relates to a display device, in particular to an electronic capable of improving a problem of heat dissipation.

### Description of Related Art

Electronic devices or splicing electronic devices have been widely used in mobile phones, televisions, monitors, tablet computers, car displays, wearable devices, and desktop computers. With the booming development of electronic devices, the quality of electronic devices has become more and more demanding.

### SUMMARY

The disclosure provides a display device capable of improving a problem of heat dissipation.

According an embodiment of the disclosure, a display device includes a substrate, multiple light emitting units, a first structure, and a second structure. The light emitting units are disposed on the substrate and generate heat. The first structure is disposed on the substrate. The second structure is disposed on an outside of the substrate. The heat is transferred from the light emitting units to the second structure through the first structure.

According to an embodiment of the disclosure, another display device includes a substrate, multiple light emitting units, a first structure, and a second structure. The light emitting units are disposed on the substrate and generate heat. The first structure is disposed on the substrate and transfers the heat. In a top view of another display device, an area of a portion of the first structure is greater than an area of a portion of the light emitting units in a predetermined square region of the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a display panel according to some embodiments of the disclosure.

FIG. 1B is a schematic cross-sectional view of the display panel of FIG. 1A taken along a line I to I′.

FIG. 2 is a schematic top view of a display panel according to some embodiments of the disclosure.

FIG. 3 is a schematic top view of a display panel according to some embodiments of the disclosure.

FIG. 4 is a schematic top view of a display panel according to some embodiments of the disclosure.

FIG. 5A is a schematic top view of a display panel according to some embodiments of the disclosure.

FIG. 5B is a schematic cross-sectional view of the display panel of FIG. 5A taken along a line II to II'.

FIG. 6A is a schematic top view of a display panel according to some embodiments of the disclosure.

FIG. 6B is a schematic cross-sectional view of the display panel of FIG. 6A taken along a line III to III'.

FIG. 7 is a schematic cross-sectional view of a display panel according to some embodiments of the disclosure.

FIG. 8 is a schematic cross-sectional view of a display panel according to some embodiments of the disclosure.

FIG. 9 is a schematic cross-sectional view of a display panel according to some embodiments of the disclosure.

FIG. 10 is a schematic cross-sectional view of a display panel according to some embodiments of the disclosure.

FIG. 11 is a schematic cross-sectional view of a display panel according to some embodiments of the disclosure.

FIG. 12 is a top three-dimensional schematic diagram of a spliced display device according to some embodiments of the disclosure.

### DESCRIPTION OF THE EMBODIMENTS

The disclosure can be understood by referring to the following detailed description and also in conjunction with the accompanying drawings. It should be noted that, for the reader’s ease of understanding and for the sake of brevity of the accompanying drawings, only a portion of the electronic device is shown in the various accompanying drawings in this disclosure, and that particular components in the accompanying drawings are not drawn to actual scale. In addition, the number and dimensions of the components in the drawings are for illustrative purposes only and are not intended to limit the scope of this disclosure.

In the following description and the claims, terms such as “include” and “comprise” are open-ended, and therefore should be interpreted as “include but not limited to.”

It should be understood that when a component or membrane layer is said to be “on” or “connected to” another component or membrane layer, it may be directly on or directly connected to such other component or membrane layer, or there may be an inserted component or membrane layer between the two (the non-direct case). Conversely, when the component is said to be “directly” on or “directly connected to” another component or membrane layer, there is no inserted component or membrane layer between the two.

It should be understood that while the terms first, second, third... may be used to describe a variety of constituent components, the constituent components are not limited to this terminology. This term is used only to distinguish a single component from other components in the specification. Instead of using the same terminology in the claims, the terms first, second, third... are substituted in the order in which the components are declared in the claims. Therefore, in the following description, the first constituent component may be the second constituent component in the claims.

The terms “approximately,” “about,” “substantially,” and “roughly” in the text usually mean within 10%, or within 5%, or within 3%, or within 2%, or within 1%, or within 0.5% of a given value or range. The quantity given here is an approximate quantity, i.e., without specifying "approximately," "about", "substantially" or "roughly", the meaning of "approximately," "about", "substantially" or "roughly" may still be implied.

In some embodiments of the disclosure, terms such as “joint”, “interconnection”, etc., unless specifically defined, may refer to two structures in direct contact, or may refer to two structures that are not in direct contact and in which other structures are provided between the two structures. The terms about connecting and joint may also include the case where both structures are movable, or where both structures are fixed. In addition, the term “coupling” includes any direct and indirect means of electrical connection.

In some embodiments of the disclosure, the area, width, thickness or height of each element, or distance or spacing between elements may be measured using optical microscopy (OM), scanning electron microscope (SEM), alpha-step (α-step), ellipsometry, or other suitable means. In detail, according to some embodiments, a scanning electron microscope may be used to obtain a cross-sectional structure image containing the elements to be measured, and to measure the area, width, thickness or height of each element, or the distance or spacing between the elements.

The electronic device may include a display device, an antenna device (such as a liquid crystal antenna), a sensing device, a light emitting device, a touch device or a splicing device, but not limited thereto. The electronic device may include a bendable and flexible electronic device. The shape of the electronic device can be rectangular, round, polygonal, with curved edges or other suitable shapes. The display device may include, for example, light emitting diode (LED), liquid crystal, fluorescence, phosphor, quantum dot (QD), other suitable materials, or a combination of the foregoing, but not limited thereto. Light emitting diodes may include, for example, organic light emitting diodes (OLED), inorganic light emitting diodes, sub-millimeter light emitting diodes (mini LED), micro light emitting diodes (micro LED), or quantum dot light emitting diodes ( QDLED), other suitable materials or any combination of the above, but not limited thereto. The display device may also include, for example, a spliced display device and a backlight module, but not limited thereto. The antenna device may be, for example, a liquid crystal antenna, but not limited thereto. The antenna device may include, for example, but not limited to, an antenna splicing device. It should be noted that the electronic device can be any combination of the aforementioned arrangements, but not limited thereto. The electronic device may have a drive system, control system, light source system, shelf system... and other peripheral systems to support the display device, antenna device or splicing device. This disclosure will be described below in terms of a display device, but the disclosure is not limited thereto.

It should be noted that the following embodiments may be used to replace, reorganize, or mix features from several different embodiments to complete other embodiments without departing from the spirit of the disclosure. The features of each embodiment can be mixed and matched as long as they do not contradict the spirit of the disclosure or conflict with each other.

Reference will now be made in detail to exemplary embodiments of the disclosure, examples of which are illustrated in the accompanying drawings. Wherever possible, the same reference numerals are used in the drawings and the description to refer to the same or like parts.

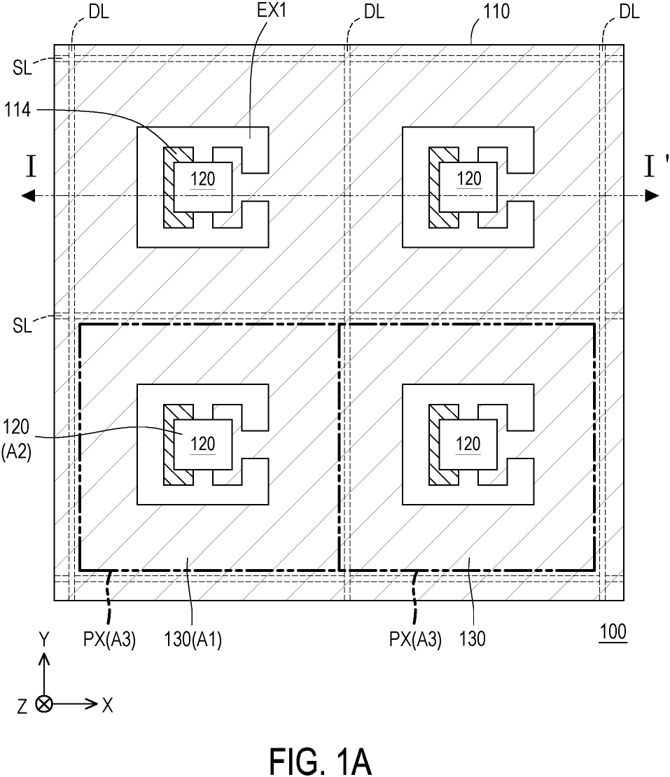

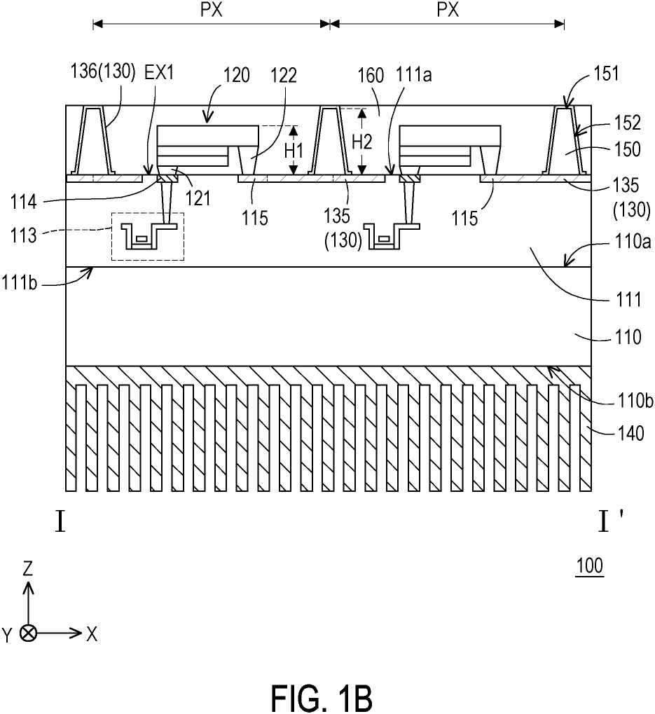

FIG. 1A is a schematic top view of a display panel according to some embodiments of the disclosure. FIG. 1B is a schematic cross-sectional view of the display panel of FIG. 1A taken along a line I to I′. For clarity of the accompanying drawings and ease of illustration, FIG. 1A omits to show certain elements in a display device 100.

Referring FIG. 1A and FIG. 1B at the same time, the display device 100 according to this embodiment includes a substrate 110, a dielectric layer 111, multiple light emitting units 120, a first structure 130, a second structure 140, and a pixel define layer (PDL) 150 and an encapsulation layer 160. The substrate 110 has a first surface 110a and a second surface 110b opposite to the first surface 110a. The substrate 110 may have thermal conductivity. In this embodiment, the substrate 110 may include a rigid substrate, a flexible substrate, or a combination of the foregoing. For example, a material of the substrate 110 may include glass, quartz, sapphire, ceramics, polycarbonate (PC), polyimide (PI), polyethylene terephthalate (PET), other suitable substrate materials, or a combination of the foregoing, but not limited thereto.

Specifically, the dielectric layer 111 is disposed on the first surface 110a of the substrate 110. The dielectric layer 111 may have a single-layer structure or a multi-layer structure. When the dielectric layer 111 has a single-layer structure, the dielectric layer 111 may have a surface 111a and a surface 111b opposite to each other. When the dielectric layer 111 has a multi-layer structure, the surface 111b may be a lower surface of a bottommost structure in contact with the first surface 110a of the substrate 110, and the surface 111a of the dielectric layer 111 may be an upper surface of a topmost structure. A transistor 113, a scan line SL and a data line DL are disposed on the first surface 110a of the substrate 110. The transistor 113 includes a semiconductor layer and a material of the semiconductor layer may include amorphous silicon, low-temperature polysilicon (LTPS), metal oxides, such as indium gallium zinc oxide (IGZO), other suitable materials, or a combination of the above, but not limited thereto. A first pad 114 and a second pad 115 are connected to the light emitting unit 120 and are respectively disposed on the surface 111a of the dielectric layer 111. The first pad 114 may be electrically connected to the transistor 113, and the second pad 115 may be electrically connected to a common signal. The scan line SL and the data line DL may be electrically connected to the transistor 113 respectively. The scan line SL and the data line DL may be interleaved with each other, but not limited thereto. A pixel unit PX may be defined by an arrangement of the scan line SL and the data line DL, and may also be defined by a range surrounded by the pixel define layer 150, but not limited thereto.

In this embodiment, a first direction X, a second direction Y, and a third direction Z are different directions. The first direction X is, for example, an extension direction of the scan line SL. The second direction Y is, for example, an extension direction of the data line DL. The third direction Z is, for example, a normal direction of the substrate 110. The first direction X is substantially perpendicular to the second direction Y, and the first direction X and the second direction Y are substantially perpendicular to the third direction Z, respectively, but not limited thereto.

The multiple light emitting units 120 are disposed on the substrate 110, and at least one of the light emitting units 120 is disposed in the pixel unit PX. In this embodiment, the multiple light emitting units 120 are disposed on the first surface 110a of the substrate 110. In a schematic cross-sectional view of the display device 100, the light emitting unit 120 may be disposed between the pixel define layer 150. The light emitting unit 120 may include light emitting diodes of different colors, such as red light emitting diodes, green light emitting diodes, and blue light emitting diodes, but not limited thereto. The light emitting unit 120 has a first electrode 121 and a second electrode 122. The first electrode 121 is connected to the first pad 114, and the second electrode 122 is connected to the second pad 115. The light emitting unit 120 may be electrically connected to the transistor 113 through the first electrode 121 and the first pad 114, and may be electrically connected to the common signal through the second electrode 122 and the second pad 115. In this embodiment, the multiple light emitting units 120 may emit light and generate heat.

In addition, in this embodiment, the light emitting unit 120 has a height H1, and the pixel define layer 150 has a height H2. When the height H2 is 0.5 times to 1.5 times the height H1, the thermal conductivity of the heat generated by the light emitting unit 120 to the first structure 130 on the pixel define layer 150 may be improved. The height H1 is a maximum height of the light emitting unit 120 measured along the third direction Z, and the height H2 is a maximum height of the pixel define layer 150 measured along the third direction Z.

The first structure 130 is disposed on the substrate 110. In this embodiment, the first structure 130 is disposed on the first surface 110a of the substrate 110. The first structure 130 may be disposed on the surface 111a of the dielectric layer 111, and includes a thermal conductive layer 135 and a thermal conductive layer 136, but not limited thereto. In this embodiment, the thermal conductive layer 135 may be formed first and then the pixel define layer 150, and the thermal conductive layer 136 formed later may be disposed on a top surface 151 and a side surface 152 of the pixel define layer 150, but not limited thereto. Other embodiments may have other setting relationships. An exposed region EX1 is located in the thermal conductive layer 135 so that the first structure 130 may expose the light emitting unit 120 as well as a portion of the dielectric layer 111. The first structure 130 may overlap the scan line SL and the data line DL in the normal direction of the substrate 110 (i.e., the third direction Z). The first structure 130 may be connected to the second pad 115 of the light emitting unit 120, but not to the first pad 114 of the light emitting unit 120. The first structure 130 may be electrically connected to the common signal, so that the first structure 130 may be configured to transmit the common signal.

In addition, in this embodiment, the first structure 130 has thermal conductivity to conduct heat. The thermal conductivity of the first structure 130 may be greater than the thermal conductivity of the encapsulation layer 160, but not limited thereto. In this embodiment, the first structure 130 may be a single-layer structure or a multi-layer structure. The first structure 130 may be a liquid cooling thermal conductivity structure or a micro-channel liquid cooling structure, but not limited thereto. A material of the first structure 130 may be a conductive and thermal conductive material such as metal, graphite or oxide conductor, and the material of the first structure 130 is also a thermal conductive material such as ceramic, but not limited thereto. The material of the first structure 130 may be the same or different from a material of the second pad 115, but not limited thereto.

In addition, in a top schematic view of the display device 100, in each of the pixel unit PX, because the first structure 130 has thermal conductivity, an area A1 of the first structure 130 may be greater than an area A2 of the light emitting unit 120, the area A1 of the first structure 130 may be greater than a half of an area A3 of the pixel unit PX (i.e., A1>½×A3), and the first structure 130 may span across the multiple light emitting units 120 or may span across multiple pixel units PX, so that the heat generated by the light emitting units 120 may be effectively and evenly dispersed and conducted outside the substrate 110 through the first structure 130, in order to achieve an effect of heat dissipation. Measurement of the area can be observed or measured in a plane formed by the direction X and the direction Y in the top schematic view.

The second structure 140 is disposed outside the substrate 110 to contact an outside world (e.g., air). In this embodiment, the second structure 140 may be under the substrate 110, and in other embodiments, the second structure 140 may be on a side of the substrate 110, but not limited thereto. The second structure 140 may be disposed on the second surface 110b of the substrate 110 and contact the second surface 110b. The second structure 140 may be a heat sink with a heat dissipation function, and the heat sink has multiple fins, but the disclosure does not limit a shape of the heat sink, as long as a surface area available for contacting the outside world can be at least greater than or equal to 50% of a total surface area of the heat sink itself. A material of the second structure 140 may be copper, aluminum or other suitable heat dissipation materials, but not limited thereto. In this embodiment, the heat generated by the multiple light emitting units 120 may be effectively conducted through the first structure 130 to the second structure 140 outside the substrate 110, and then through the second structure 140 to the outside world (e.g., air) to achieve the effect of heat dissipation. In some embodiments, the second structure 140 may be a final element that conducts heat to the outside world (e.g., air) or the final element that contacts the outside world, but is not limited thereto.

Other embodiments are set forth below for illustrative purposes. It should be noted here that the following embodiments follow the numeral references and parts of the previous embodiments, where the same numeral references are used to indicate the same or similar components, and the description of the same technical content is omitted. The description of the omitted parts can be found in the preceding embodiments, and will not be repeated in the following embodiments.

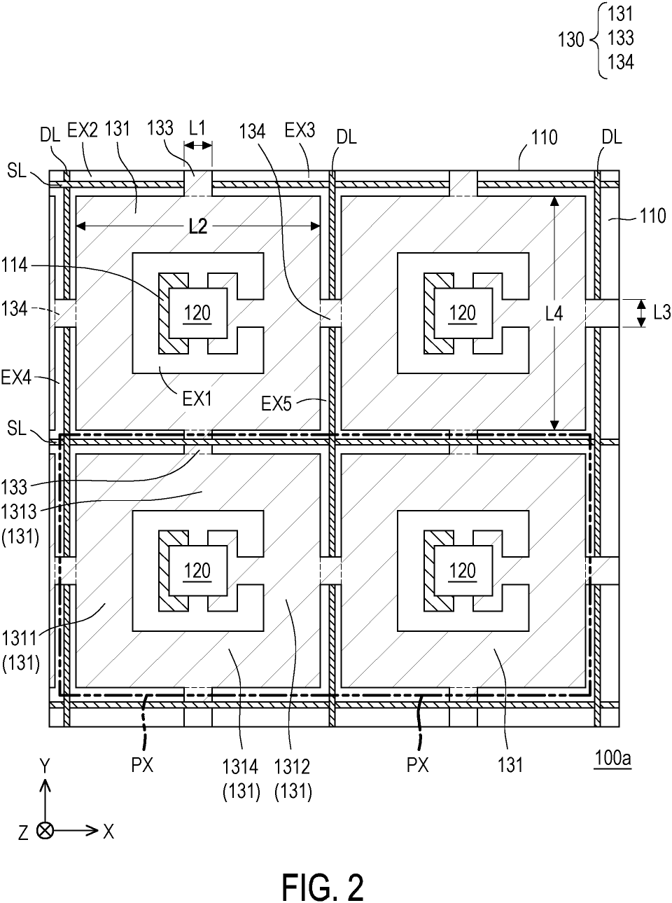

FIG. 2 is a schematic top view of a display panel according to some embodiments of the disclosure. Referring to FIG. 1A and FIG. 2 at the same time, a display device 100a according to this embodiment is substantially similar to the display device 100 of FIG. 1A, so the same and similar components of the two embodiments are not repeated here. One of differences between the display device 100a according to this embodiment and the display device 100 is that the first structure 130 includes a bridge 133, a bridge 134, and multiple frames 131. In a top view, the bridge 133 is located between two adjacent exposed regions EX2 and EX3 (or between two adjacent exposed regions EX4 and EX5), and the bridge 134 is located between two adjacent exposed regions EX2 and EX4 (or between two adjacent exposed regions EX3 and EX5), and other similar components will not be repeated here, while the frames 131 are located within the exposed regions EX2 to EX5 and the bridges 133 and 134.

Each of the frame 131 is disposed in the each of the pixel unit PX. In two adjacent pixel units PX, the frame 131 in one of the pixel unit PX may be connected to the frame 131 in the other pixel unit PX, but it not limited thereto. In this embodiment, the frame 131 may, for example, be visualized as a rectangle or quadrilateral with four side edges, but not limited thereto.

Specifically, the frame 131 may include a first side 1311, a second side 1312, a third side 1313, and a fourth side 1314. The first side 1311 and the second side 1312 are opposite to each other, and the third side 1313 and the fourth side 1314 are opposite to each other. The third side 1313 connects the first side 1311 and the second side 1312, and the fourth side 1314 connects the first side 1311 and the second side 1312. In this embodiment, one light emitting unit 120 is disposed in the each of the pixel unit PX. In the each of the pixel unit PX, the first side 1311, the second side 1312, the third side 1313, and the fourth side 1314 of the frame 131 may be respectively disposed around the light emitting unit 120 to surround the light emitting unit 120. That is, in this embodiment, the multiple light emitting units 120 may be respectively disposed in the pixel unit PX, and one light emitting unit 120 in the each of the pixel unit PX may be surrounded by the frame 131.

Specifically, referring FIG. 2, in this embodiment, the frame 131 in the first structure 130 may not overlap the scan line SL and the data line DL in the normal direction of the substrate 110 (i.e., the third direction Z) to reduce parasitic capacitance between the frame 131 and the scan line SL and to reduce parasitic capacitance between the frame 131 and the data line DL.

In this embodiment, the bridge 133 and the bridge 134 are disposed between two adjacent frames 131 to connect two adjacent frames 131 of the multiple frames 131. That is, in two adjacent pixel units PX, the frame 131 in one of the pixel units PX may be connected to the frame 131 in the other pixel unit PX through the bridge 133 or the bridge 134. In addition, the bridge 133 may overlap the scan line SL in the normal direction of the substrate 110 (i.e., the third direction Z), and the bridge 134 may overlap the data line DL in the normal direction of the substrate 110 (i.e., the third direction Z). In this embodiment, a length L1 of the bridge 133 in the first direction X is less than a length L2 of the frame 131 in the first direction X, and a length L3 of the bridge 134 in the second direction Y is less than a length L4 of the frame 131 in the second direction Y, thereby reducing parasitic capacitance between the first structure 130 and the scan line SL and reducing parasitic capacitance between the first structure 130 and the data line DL.

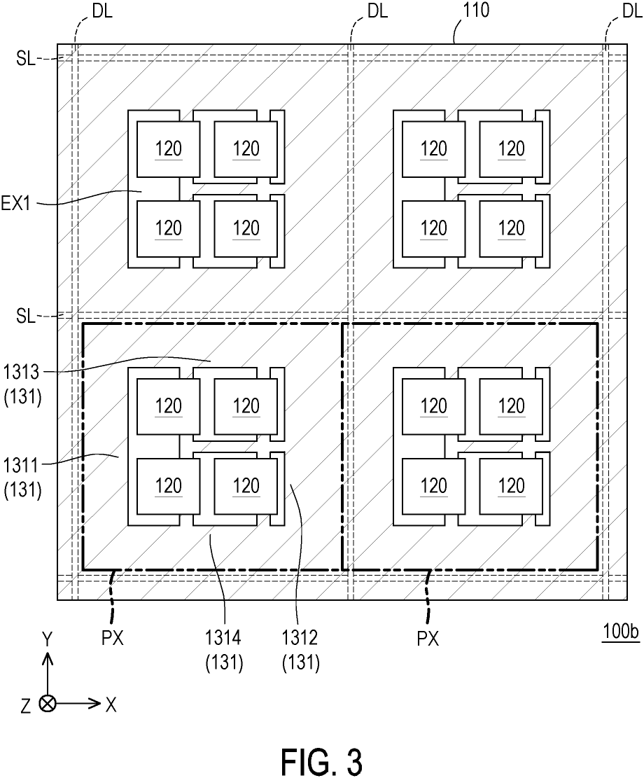

FIG. 3 is a schematic top view of a display panel according to some embodiments of the disclosure. Referring FIG. 1A and FIG. 3 at the same time, a display device 100b according to this embodiment is substantially similar to the display device 100 of FIG. 1A, so the same and similar components of the two embodiments are not repeated here. One of the differences between the display device 100b according to this embodiment and the display device 100 is that in the display device 100b according to this embodiment, the multiple light emitting units 120 are disposed in the each of the pixel unit PX.

Specifically, referring FIG. 3, in this embodiment, for example, four light emitting units 120 are disposed in the each of the pixel unit PX. However, the disclosure does not limit a number of the light emitting units 120 disposed in the each of the pixel unit PX, as long as the number of the light emitting units 120 is 2 or more. In some embodiments, in the each of the pixel unit PX, the first side 1311, the second side 1312, the third side 1313, and the fourth side 1314 of the frame 131 as shown in FIG. 2 may be disposed around the multiple light emitting units 120, respectively, to surround the multiple light emitting units 120. That is, the multiple light emitting units 120 in the each of the pixel unit PX may be surrounded by the frame 131.

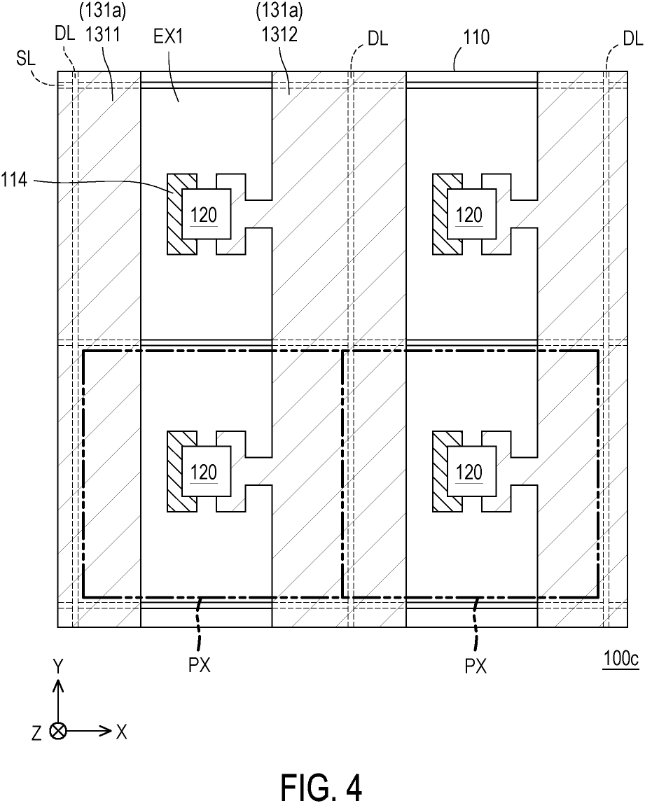

FIG. 4 is a schematic top view of a display panel according to some embodiments of the disclosure. Referring FIG. 2 and FIG. 4 at the same time, a display device 100c according to this embodiment is substantially similar to the display device 100 of FIG. 2, so the same and similar components in the two embodiments will not be repeated here. One of the differences between the display device 100c according to this embodiment and the display device 100 is that in the display device 100c according to this embodiment, a frame 131a in the each of the pixel unit PX surrounds the light emitting unit 120.

Specifically, referring FIG. 4, in this embodiment, the frame 131a in the first structure 130 in the each of the pixel unit PX includes two sides, for example, the first side 1311 and the second side 1312 opposite to each other, but not limited thereto. In some embodiments, the two sides may also be the first side 1311 and the third side 1313, the first side 1311 and the fourth side 1314, the second side 1312 and the third side 1313, or the second side 1312 and the fourth side 1314 in FIG. 2. In some embodiments, the frame in the first structure 130 may also include at least one side of the first structure 130 in FIG. 2 to surround the light emitting unit 120, for example, any one side or any three sides of the first structure 130 in FIG. 2 may surround the light emitting unit 120.

In this embodiment, since a portion of the scan line SL may not overlap the frame 131a of the first structure 130 in the normal direction of the substrate 110 (i.e., the third direction Z), the parasitic capacitance between the first structure 130 and the scan line SL may be reduced.

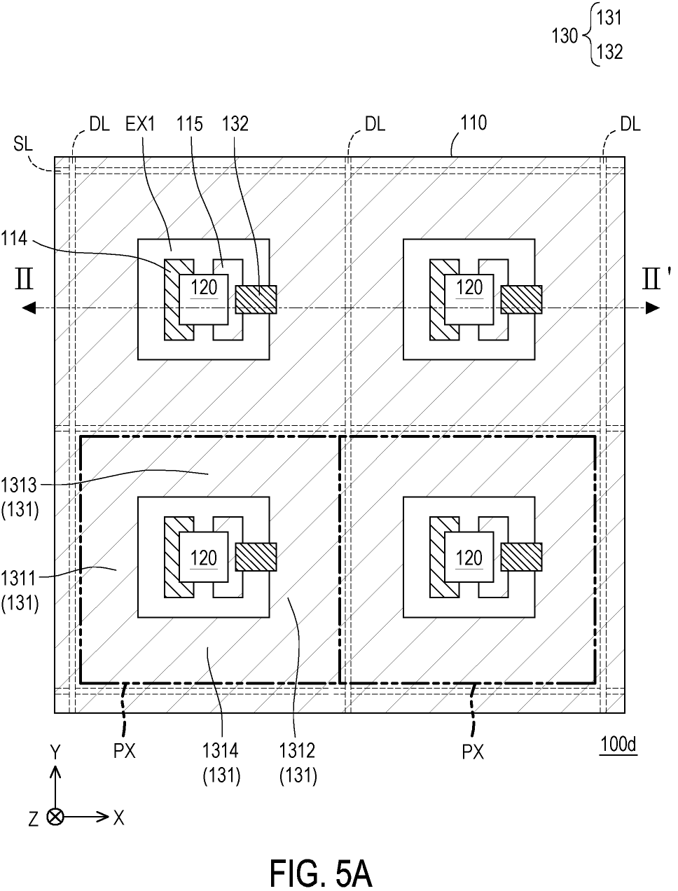

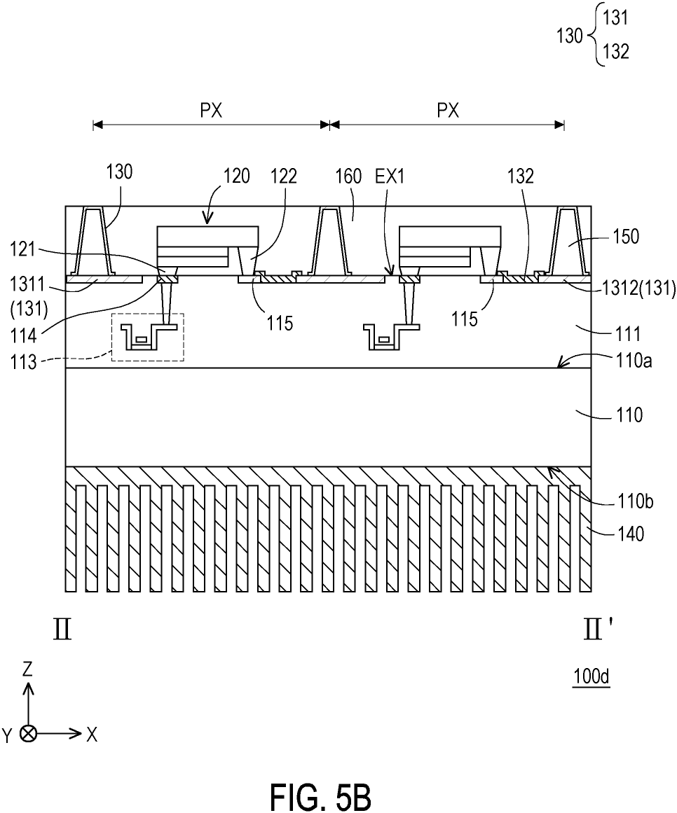

FIG. 5A is a schematic top view of a display panel according to some embodiments of the disclosure. FIG. 5B is a schematic cross-sectional view of the display panel of FIG. 5A taken along a line II to II'. Referring FIG. 1A to FIG. 1B and FIG. 5A to FIG. 5B at the same time, a display device 100d according to this embodiment is substantially similar to the display device 100 of FIGS. 1A to FIG.1B, so the same and similar components in the two embodiments are not repeated here. One of the differences between the display device 100d according to this embodiment and the display device 100 is that in the display device 100d according to this embodiment, the first structure 130 includes multiple frames 131 and multiple connectors 132. The connector 132 is disposed between the light emitting unit 120 and the frame 131 in the each of the pixel unit PX to connect the second pad 115 of the light emitting unit 120 and the frame 131. A material of the connector 132 of the first structure 130 may be the same or different from a material of the frame 131, increasing design flexibility according to demand, such as increasing electrical conductivity, increasing thermal conductivity, reducing a risk of wire breakage, increasing capacitance, facilitating wire layout, but not limited thereto.

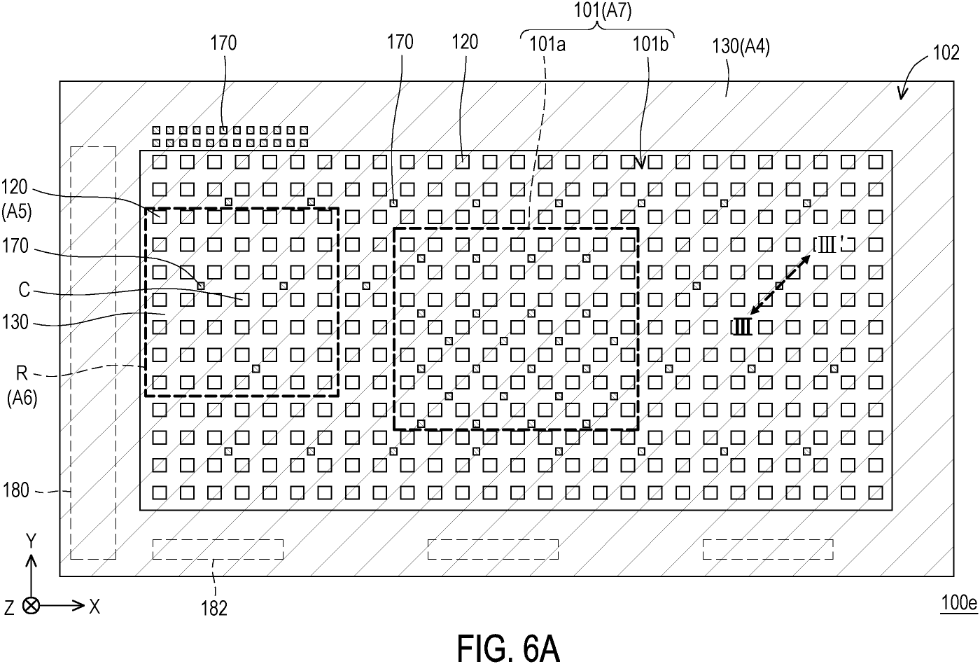

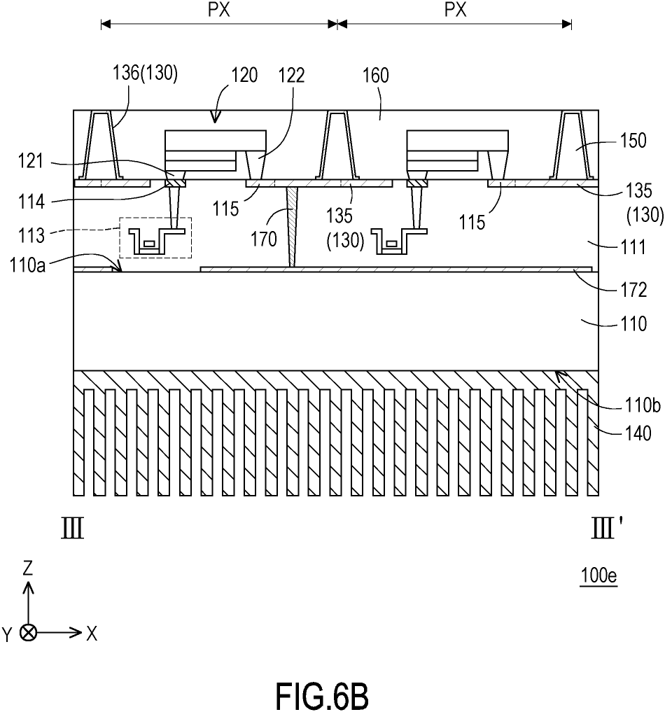

FIG. 6A is a schematic top view of a display panel according to some embodiments of the disclosure. FIG. 6B is a schematic cross-sectional view of the display panel of FIG. 6A taken along a line III to III'. Referring FIG. 1A to FIG. 1B and FIG. 6A to FIG. 6B at the same time, a display device 100e according to this embodiment is substantially similar to the display device 100 of FIGS. 1A to FIG.1B, so the same and similar components in the two embodiments are not repeated here. One of the differences between the display device 100e according to this embodiment and the display device 100 is that the display device 100e according to this embodiment has a display region 101 and a non-display region 102 adjacent to the display region 101. The display region 101 includes a first region 101a and a second region 101b, and the display device 100e further includes a third structure 170, a fourth structure 172, a gate driver 180, and a data driver 182.

Specifically, referring FIG. 6A and FIG. 6B, in this embodiment, the multiple light emitting units 120 and the pixel define layer 150 are disposed in the display region 101. The gate driver 180 and the data driver 182 are disposed in the non-display region 102. The first structure 130, the third structure 170, and the fourth structure 172 are disposed in the display region 101 and the non-display region 102. In a schematic top view of the display device 100e (as shown in FIG. 6A), the third structure 170 may be staggered or irregularly arranged in the display region 101, but not limited thereto. In some embodiments, the third structure may also be arranged in an array in the display region 101 (not shown).

More specifically, the fourth structure 172 is disposed on the first surface 110a of the substrate 110 and is located between the dielectric layer 111 and the substrate 110. The first structure 130 and the fourth structure 172 are respectively located on opposite sides of the dielectric layer 111. The fourth structure 172 has thermal conductivity, and a material of the fourth structure 172 may be the same or different from the material of the first structure 130, and therefore will not be repeated here.

The third structure 170 is disposed on the first surface 110a of the substrate 110 and penetrates the dielectric layer 111. The third structure 170 may connect the second pad 115 (or the first structure 130) and the fourth structure 172.

In this embodiment, a structure type of the third structure 170 may be, for example, a thermally conductive connection structure, but the disclosure does not limit the structure type of the third structure 170, as long as the third structure 170 may connect to the second pad 115 (or the first structure 130 ) to the fourth structure 172. In this embodiment, because the third structure 170 and the fourth structure 172 both have thermal conductivity, the heat generated by the multiple light emitting units 120 may be effectively conducted through the first structure 130, the third structure 170, and the fourth structure 172 to the substrate 110, and then through the second structure 140 to the outside world (e.g., air) to achieve the effect of heat dissipation. In this embodiment, a material of the third structure 170 and the fourth structure 172 may be the same or different from the material of the first structure 130, but not limited thereto.

In a schematic top view of the display device 100e (as shown in FIG. 6A), the third structure 170 has a first density in the non-display region 102, has a second density in the first region 101a of the display region 101, and has a third density in the second region 101b of the display region 101. The density may be a number of the third structure 170 in a same unit area in the schematic top view (e.g., a plane formed by the direction X and the direction Y). The unit area may be 1×1 cm, 2×2 cm, 3×3 cm, etc., but not limited thereto. The first density may be different from the second density and the third density. For example, the first density may be greater than the second density and the third density, or the first density may be greater than the second density and the second density may be greater than the third density, but not limited thereto. In some embodiments, the second density may also be equal to the third density (not shown). In product design, a region of the third structure 170 may be disposed according to heat energy distribution, and in principle, a higher density of the third structure 170 may help the heat energy to be discharged more quickly. In some embodiments, the third structure 170 is not designed to be in the non-display region 102, i.e., there is no first density in the non-display region 102, but only the second density and the third density, where the second density may be greater than the third density, or the second density may be equal to the third density (not shown), but not limited thereto. In some embodiments, the third structure 170 is not designed to be in the first region 101a and the second region 101b of the display region 101, i.e., there is no second density and third density. The third structure 170 is only in the non-display region 102, but is not limited to in one corner of the non-display region 102 as shown in FIG. 6A, and the third structure 170 may be designed anywhere in the non-display region 102 according to design requirements.

In a top view of the display device 100e (as shown in FIG. 6A), since an area A4 of the first structure 130 in a predetermined square region R of the substrate 110 may be greater than an area A5 of all the light emitting units 120 in the predetermined square region R (i.e., A4>A5), and the area A4 of the first structure 130 in the predetermined square region R may be greater than a half of an area A6 of the predetermined square region R (i.e., A4>½×A6), so that the heat generated by the multiple light emitting units 120 may be effectively and evenly dispersed and conducted outside the substrate 110 through the first structure 130 to achieve the effect of heat dissipation. The predetermined square region R is located in the display region 101, the area A6 of the predetermined square region R is at least 10% of the area A7 of the display region 101 (i.e., A6 ≥ 10%×A7), and a center point C of the predetermined square region R is a center point of the light emitting unit 120.

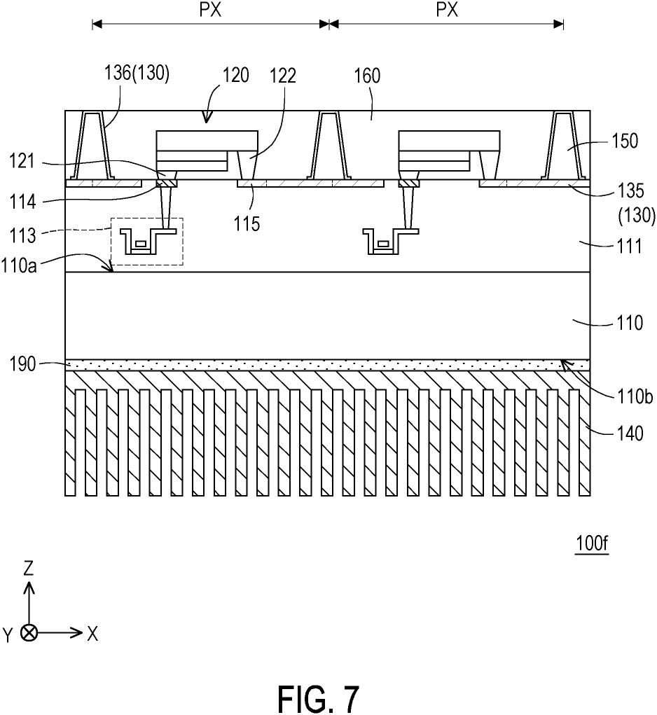

FIG. 7 is a schematic cross-sectional view of a display panel according to some embodiments of the disclosure. Referring FIG. 1B and FIG. 7 at the same time, a display device 100f according to this embodiment is substantially similar to the display device 100 of FIG. 1B, so the same and similar components in the two embodiments are not repeated here. One of differences between the display device 100f according to this embodiment and the display device 100 is that the display device 100f according to this embodiment further includes a medium 190.

Specifically, referring FIG. 7, in this embodiment, the medium 190 is disposed between the second surface 110b of the substrate 110 and the second structure 140, so that the medium 190 may contact the substrate 110 and the second structure 140, and so that the second structure 140 may be connected to the first structure 130 through the medium 190 and the substrate 110. In this embodiment, the medium 190 may contact the outside world, and a surface area of the medium 190 available to contact the outside world may be less than 50% of its own total surface area. A material of the medium 190 is, for example, thermal paste, but not limited thereto.

In this embodiment, because the medium 190 has thermal conductivity, the heat generated by the multiple light emitting units 120 may be effectively conducted through the first structure 130 to the substrate 110, and then through the medium 190 and the second structure 140 to the outside world (e.g., air) to achieve the effect of heat dissipation.

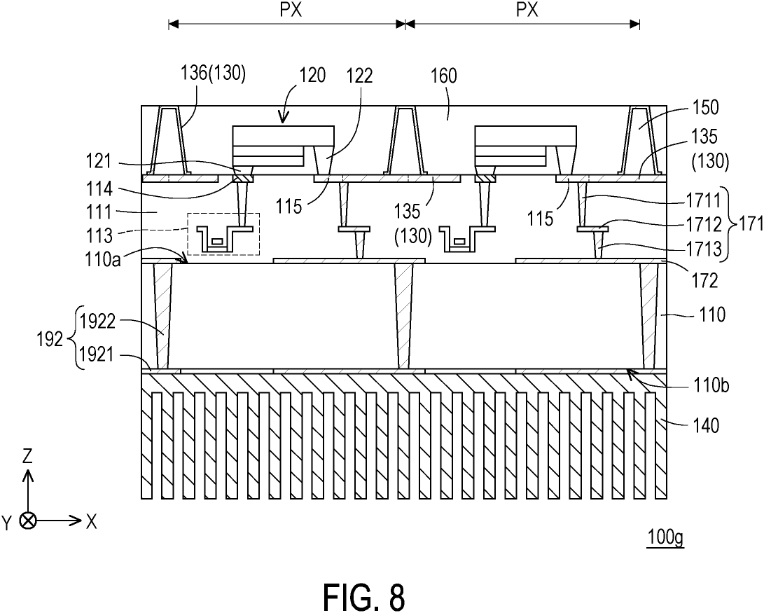

FIG. 8 is a schematic cross-sectional view of a display panel according to some embodiments of the disclosure. Referring FIG. 6B and FIG. 8 at the same time, a display device 100g according to this embodiment is substantially similar to the display device 100e of FIG. 6B, so the same and similar components in the two embodiments will not be repeated here. One of differences between the display device 100g according to this embodiment and the display device 100e is that the display device 100g according to this embodiment further includes a medium 192.

Specifically, referring FIG. 8, in this embodiment, the medium 192 is disposed on the second surface 110b of the substrate 110 and in the substrate 110, so that the medium 192 may connect the fourth structure 172 and the second structure 140, and so that the second structure 140 may be connected to the first structure 130 through the medium 192, the fourth structure 172, and the third structure 171.

In this embodiment, the medium 192 includes a thermal conductive layer 1921 and a thermally conductive medium connection structure 1922. The thermal conductive layer 1921 is disposed between the second surface 110 b of the substrate 110 and the second structure 140, so that the thermal conductive layer 1921 may connect the substrate 110 and the second structure 140. The thermally conductive medium connection structure 1922 penetrates the substrate 110 to connect the fourth structure 172 and the thermal conductive layer 1921. In addition, in this embodiment, the medium 192 may contact the outside world, and a surface area of the medium 192 available to contact the outside world may be less than 50% of its own total surface area. A material of the medium 192 may be the same or different from the material of the first structure 130, but not limited thereto.

In this embodiment, the third structure 171 includes a thermally conductive connection structure 1711, a thermal conductive layer 1712, and a thermally conductive connection structure 1713. The third structure 171 is disposed on the substrate 110. For example, the thermally conductive connection structure 1711 and the thermally conductive connection structure 1713 respectively penetrate a portion of the dielectric layer 111, and the thermally conductive connection structure 1711 and the thermally conductive connection structure 1713 may be connected through the thermal conductive layer 1712. In some embodiments, a structure type of the third structure 171 may be different depending on requirements, as long as the third structure 171 may connect the first structure 130 and the fourth structure 172.

In this embodiment, because the medium 192 has thermal conductivity, the heat generated by the multiple light emitting units 120 may be effectively conducted through the first structure 130, the third structure 171, and the fourth structure 172 to the substrate 110, and then through the medium 192 and second structure 140 to the outside world (e.g., air) to achieve the effect of the effect of heat dissipation.

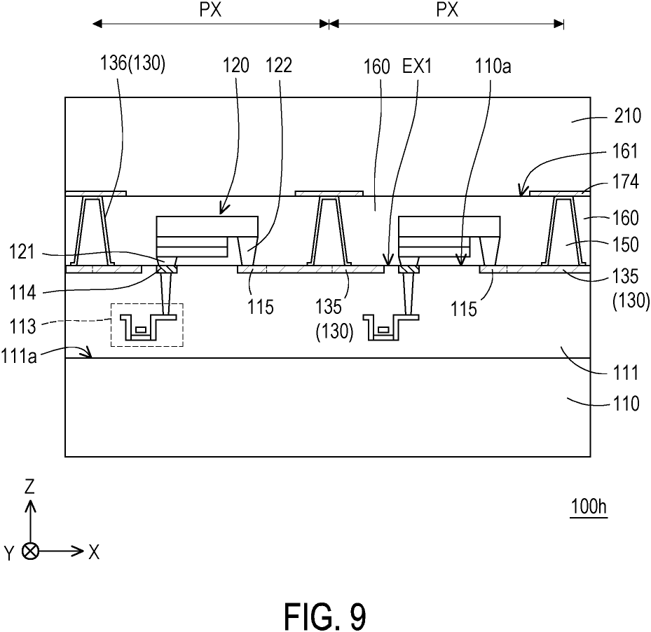

FIG. 9 is a schematic cross-sectional view of a display panel according to some embodiments of the disclosure. Referring FIG. 1B and FIG. 9 at the same time, a display device 100h according to this embodiment is substantially similar to the display device 100 of FIG. 1B, so the same and similar components in the two embodiments are not repeated here. One of differences between the display device 100h according to this embodiment and the display device 100 is that the display device 100h according to this embodiment further includes a fifth structure 174 and a substrate 210.

Specifically, referring FIG. 9, in this embodiment, the fifth structure 174 is disposed on a surface 161 of the encapsulation layer 160 away from the substrate 110, and the fifth structure 174 may be connected to the first structure 130. A material of the fifth structure 174 may be the same or different from the material of the first structure 130, but not limited thereto.

The substrate 210 and the substrate 110 are disposed opposite to each other, and the substrate 210 and the substrate 110 are respectively disposed on opposite sides of the encapsulation layer 160. The substrate 210 may be disposed on the surface 161 of the encapsulation layer 160 to cover and connect the fifth structure 174. The substrate 210 may contact the outside world. A material of the substrate 210 may be the same or different from the material of the substrate 110, but not limited thereto.

In this embodiment, because the fifth structure 174 and the substrate 210 have thermal conductivity, the heat generated by the multiple light emitting units 120 may be effectively conducted through the first structure 130 and the fifth structure 174 to the substrate 210, and then through the substrate 210 is conducted to the outside world (e.g., air) to achieve the effect of heat dissipation.

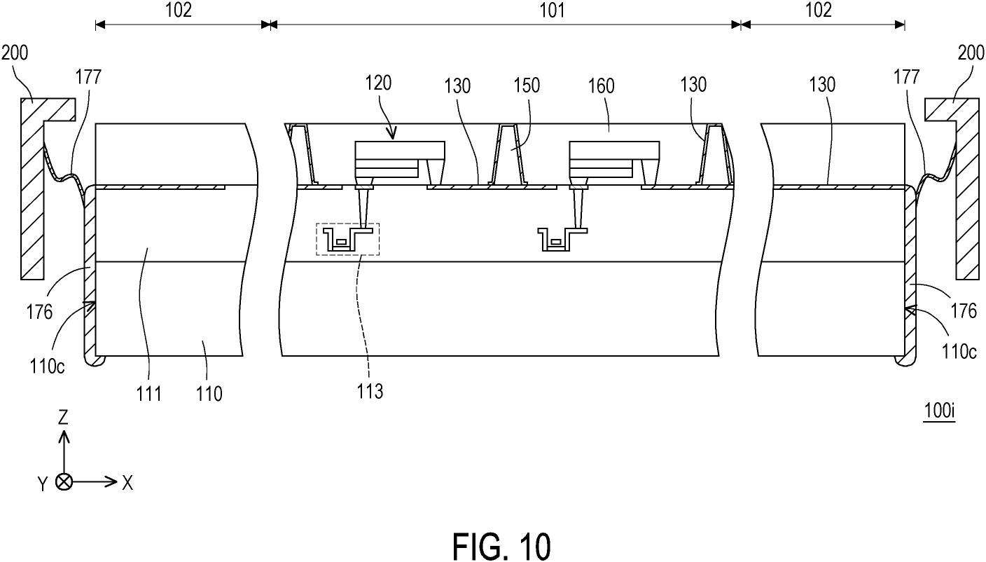

FIG. 10 is a schematic cross-sectional view of a display panel according to some embodiments of the disclosure. Referring FIG. 1B and FIG. 10 at the same time, a display device 100i according to this embodiment is substantially similar to the display device 100 of FIG. 1B, so the same and similar components in the two embodiments are not repeated here. One of differences between the display device 100i according to this embodiment and the display device 100 is that the display device 100i according to this embodiment has the display region 101 and the non-display region 102 adjacent to the display region 101, and the display device 100i further includes a sixth structure 176, a metal wire 177, and a carrier 200.

Specifically, referring FIG. 10, in this embodiment, the multiple light emitting units 120 and the pixel define layer 150 are disposed in the display region 101. The first structure 130 is disposed in the display region 101 and the non-display region 102. The sixth structure 176, the metal wire 177, and the carrier 200 are disposed in the non-display region 102.

More specifically, the sixth structure 176 is disposed on a side 110c of the substrate 110. The sixth structure 176 may connect the first structure 130 and the second structure 140 (not shown), so that the first structure 130 may be connected to the second structure 140 through the sixth structure 176. A material of the sixth structure 176 may be the same or different from the material of the first structure 130, but not limited thereto. The carrier 200 is disposed on a periphery of the display device 100i and may contact the outside world. In this embodiment, the carrier 200 may be connected to the sixth structure 176 through the metal wire 177, but not limited thereto. In some embodiments, the carrier 200 may also contact the sixth structure, thus eliminating a need for additional metal wires (not shown). A material of the carrier 200 is, for example, aluminum, aluminum alloy or other suitable metal or ceramic, plastic materials, but not limited thereto.

In this embodiment, because the sixth structure 176 and the metal wire 177 have thermal conductivity, and the carrier 200 has the heat dissipation function, the heat generated by the multiple light emitting units 120 may be effectively conducted through the first structure 130, the sixth structure 176, and the metal wire 177 to the carrier 200, and then through the carrier 200 to the outside world (e.g., air) to achieve the effect of heat dissipation.

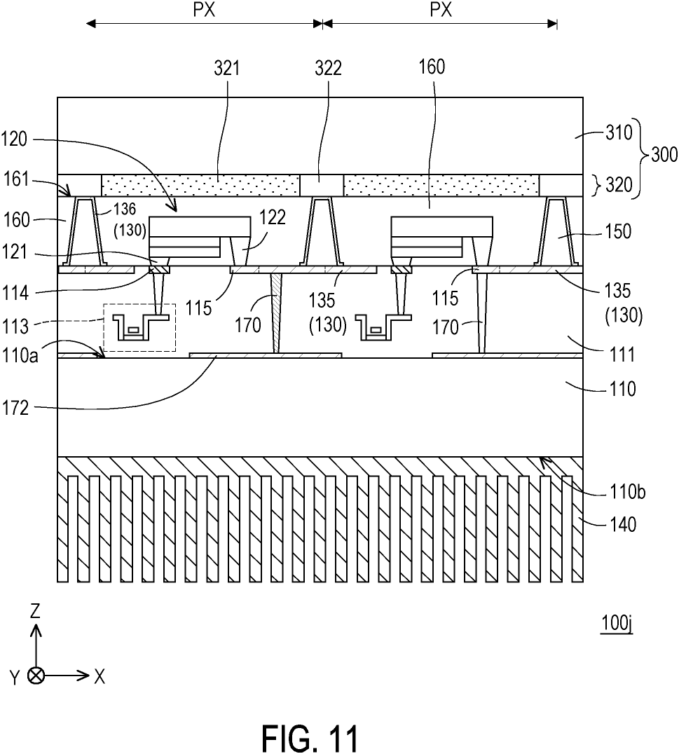

FIG. 11 is a schematic cross-sectional view of a display panel according to some embodiments of the disclosure. Referring FIG. 6B and FIG. 11 at the same time, a display device 100j according to this embodiment is substantially similar to the display device 100e of FIG. 6B, so the same and similar components in the two embodiments are not repeated here. One of differences between the display device 100j according to this embodiment and the display device 100e is that the display device 100j according to this embodiment further includes a color filter substrate 300.

Specifically, referring FIG. 11, in this embodiment, the color filter substrate 300 is disposed on the surface 161 of the encapsulation layer 160 away from the substrate 110, so that the color filter substrate 300 and the substrate 110 are respectively disposed on opposite sides of the encapsulation layer 160. The color filter substrate 300 includes a substrate 310 and an optical layer 320 disposed on the substrate 310. The optical layer 320 is located between the substrate 310 and the encapsulation layer 160. The optical layer 320 includes a color conversion layer 321 and a black matrix 322 disposed adjacently. The color conversion layer 321 is disposed corresponding to the light emitting unit 120, and the black matrix 322 is disposed corresponding to the pixel define layer 150. In some embodiments, the color conversion layer 321 may be replaced with a color filter layer as needed.

In this embodiment, the third structure 170 and the fourth structure 172 may be disposed corresponding to the each of the light emitting unit 120, so that the heat generated by the each of the light emitting unit 120 may effectively conducted through the first structure 130, the third structure 170 corresponding to the light emitting unit 120, and the fourth structure 172 corresponding to light emitting unit 120 to the substrate 110, and then through the second structure 140 to the outside world (e.g., air) to achieve the effect of heat dissipation.

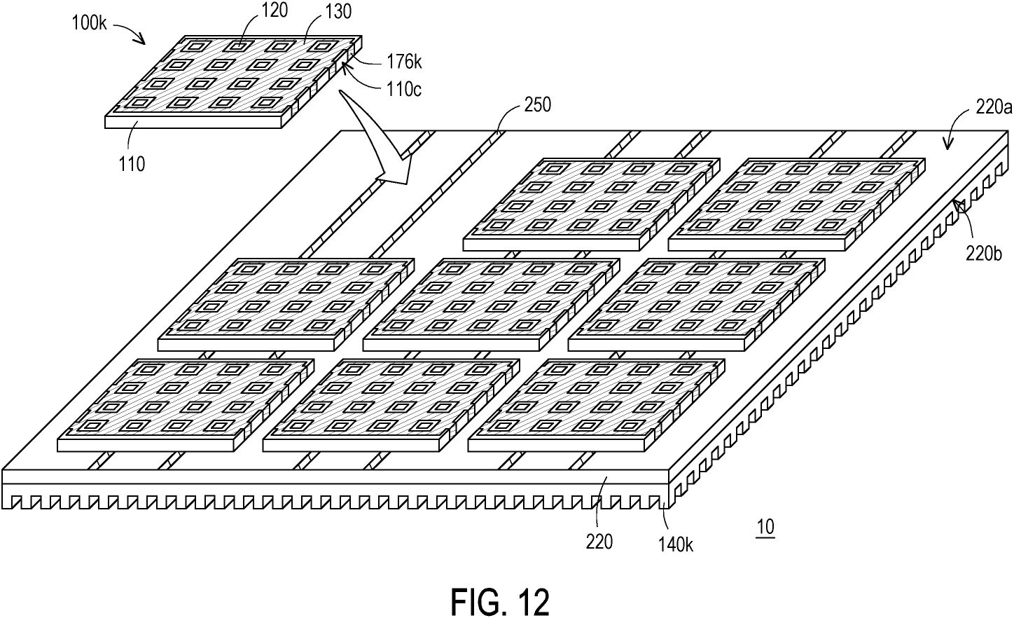

FIG. 12 is a top three-dimensional schematic diagram of a spliced display device according to some embodiments of the disclosure. Referring FIG. 12 first, a spliced display device 10 according to this embodiment includes multiple display devices 100k, a thermal conductive element 250, a substrate 220, and a second structure 140k. Next, referring FIG. 1B and FIG. 12 at the same time, the display device 100k according to this embodiment is substantially similar to the display device 100 of FIG. 1B, so the same and similar components in the two embodiments are not repeated here. One of differences between the display device 100k according to this embodiment and the display device 100 is that the display device 100k according to this embodiment further includes a sixth structure 176k.

Specifically, referring FIG. 12, in this embodiment, the substrate 220 has a first surface 220a and a second surface 220b opposite to the first surface 220a. The thermal conductive element 250 is disposed on the first surface 220a of the substrate 220. A material of the thermal conductive element 250 may be the same or different from the material of the first structure 130, and therefore will not be repeated here. Multiple display devices 100k are arranged in array on the first surface 220a of the substrate 220 to cover the thermal conductive element 250. The second structure 140k is disposed on the second surface 220b of the substrate 220. The sixth structure 176k is disposed on the side 110c of the substrate 110 to connect to the first structure 130. A material of the sixth structure 176k may be the same or different from the material of the first structure 130, but not limited thereto.

In this embodiment, because the thermal conductive element 250 has thermal conductivity and the second structure 140k has the heat dissipation function, the heat generated by the multiple light emitting units 120 may be effectively conducted through the first structure 130, the substrate 110, and the thermal conductive element 250 to the substrate 220, and then through the second structure 140k to the outside world (e.g., air) to achieve the effect of heat dissipation.

In addition, in this embodiment, because the sixth structure 176k has thermal conductivity, the heat generated by the multiple light emitting units 120 may also be effectively conducted through the first structure 130 and the sixth structure 176k to the substrate 220, and then through the second structure 140k to the outside world (e.g., air) to achieve the effect of heat dissipation.

In summary, in the display device according to the embodiment of the disclosure, the area of the first structure disposed on the substrate is greater than the area of the multiple light emitting units, and the first structure has thermal conductivity, so that the heat generated by the multiple light emitting units may be effectively and evenly dispersed and conducted through the first structure to the second structure outside the substrate, and then through the second structure to the outside world (e.g., air) to achieve the effect of heat dissipation. Since the third structure, the fourth structure, the fifth structure, the sixth structure, and the medium all have thermal conductivity, after being conducted to the first structure, the heat generated by the multiple light emitting units may be conducted through the third structure, the fourth structure, the fifth structure, the sixth structure, and/or the medium to the substrate and/or the second structure, and then to the outside world (e.g., air) to achieve the effect of heat dissipation. Furthermore, for measurement of heat energy, temperature data may be measured by measuring instruments such as infrared sensors or infrared cameras to know a distribution of the heat energy.

Finally, it should be noted that the above embodiments are intended only to illustrate the technical solutions of the disclosure and not to limit them. Although the disclosure is described in detail with reference to the foregoing embodiments, it will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device comprising:
a substrate;
a plurality of light emitting units disposed on the substrate and generating heat;
a first structure disposed on the substrate; and
a second structure disposed on an outside of the substrate,
wherein the heat is transferred from the light emitting units to the second structure through the first structure.

2. The display device according to claim 1, wherein the first structure comprises a plurality of frames, and at least one of the light emitting units is surrounded by one of the frames.

3. The display device according to claim 2, wherein the first structure further comprises a bridge connecting two adjacent ones of the frames.

4. The display device according to claim 1, wherein the first structure is configured to transmit a common signal.

5. The display device according to claim 1 further comprising:
a medium, wherein the second structure is connected to the first structure through the medium.

6. A display device comprising:
a substrate;
a plurality of light emitting units disposed on the substrate and generating heat; and
a first structure disposed on the substrate and transferring the heat,
wherein in a top view of the display device, an area of a portion of the first structure is greater than an area of a portion of the light emitting units in a predetermined square region of the substrate.

7. The display device according to claim 6, wherein the area of the portion of the first structure is greater than a half of an area of the predetermined square region.
